(19) United States
(12) Patent Application Publication
(10) Pub. No.: US 2025/0203859 A1
(43) Pub. Date: Jun. 19, 2025

(54) ROM DEVICE, LAYOUT, AND METHOD

(71) Applicant: TAIWAN SEMICONDUCTOR MANUFACTURING COMPANY, LTD., Hsinchu (TW)

(72) Inventors: Preciliano Asinas RUIZ, JR., Hsinchu (TW); Chien-Ying CHEN, Hsinchu (TW); Ku-Feng LIN, Hsinchu (TW)

(21) Appl. No.: 18/660,959

(22) Filed: May 10, 2024

Related U.S. Application Data
(60) Provisional application No. 63/611,515, filed on Dec. 18, 2023.

(51) Int. Cl. H10B 20/00

(52) U.S. Cl. CPC H10B 20/387

(57) ABSTRACT

A read-only memory (ROM) array includes first through fourth rows of ROM bits including respective first through fourth adjacent active areas. Each of the first through fourth rows of ROM bits includes a total of four adjacent ROM bits positioned along the corresponding one of the first through fourth active areas, each ROM bit of the total of four ROM bits of each row of ROM bits includes two source/drain (S/D) regions in the corresponding active area, and three of the S/D regions of each row of ROM bits are shared by the four ROM bits.

### PRIORITY CLAIM

The present application claims the priority of U.S. Provisional Application No. 63/611,515, filed Dec. 18, 2023, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are respective plan and side views of an IC device and layout diagram, in accordance with some embodiments.

FIGS. 2A and 2B are a respective schematic diagram and plan view of an IC device and layout diagram, in accordance with some embodiments.

FIGS. 3A and 3B are a respective schematic diagram and plan view of an IC device and layout diagram, in accordance with some embodiments.

FIGS. 4A and 4B are a respective schematic diagram and plan view of an IC device and layout diagram, in accordance with some embodiments.

FIGS. 5A and 5B are a respective schematic diagram and plan view of an IC device and layout diagram, in accordance with some embodiments.

FIG. 6 is a plan view of an IC device and layout diagram, in accordance with some embodiments.

FIGS. 7A and 7B are a respective schematic diagram and plan view of an IC device and layout diagram, in accordance with some embodiments.

FIG. 8 is a flowchart of a method of manufacturing an IC, in accordance with some embodiments.

FIG. 9 is a flowchart of a method of generating an IC layout diagram, in accordance with some embodiments.

FIG. 10 is a block diagram of an IC layout diagram generation system, in accordance with some embodiments.

FIG. 11 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a read-only memory (ROM) integrated circuit (IC) device and corresponding layout diagram and manufacturing method include four rows of ROM bits positioned on four adjacent active areas, each row having a total of four ROM bits, each of which includes a gate portion and two adjacent source/drain (S/D) regions in the corresponding active area. Three of the four S/D regions in each row are shared by the four ROM bits such that a row length corresponds to five times a gate pitch.

Compared to other approaches, e.g., those in which a total of two S/D regions shared among four ROM cells correspond to a row length of six times a gate pitch, the ROM device is capable of having a smaller area, reduced bit line length, and less variable bit line leakage.

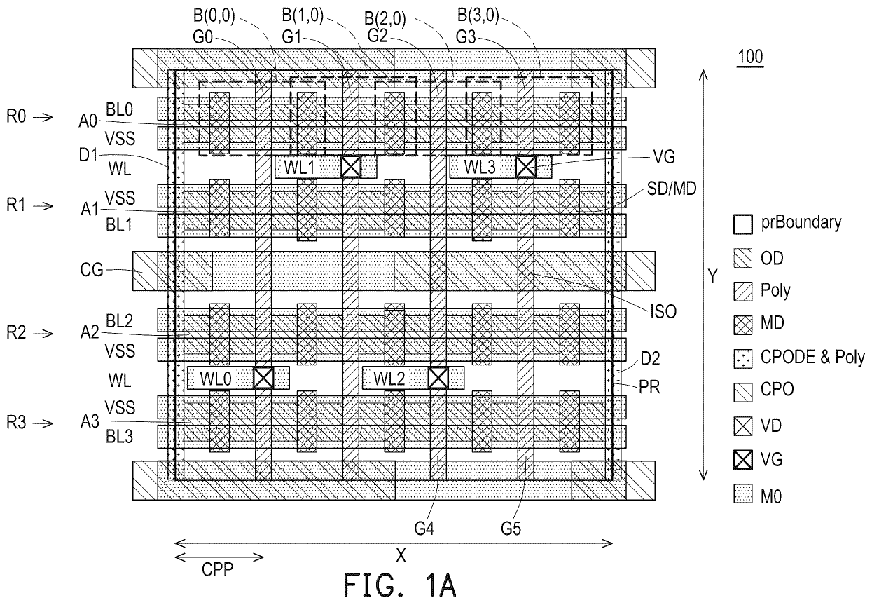

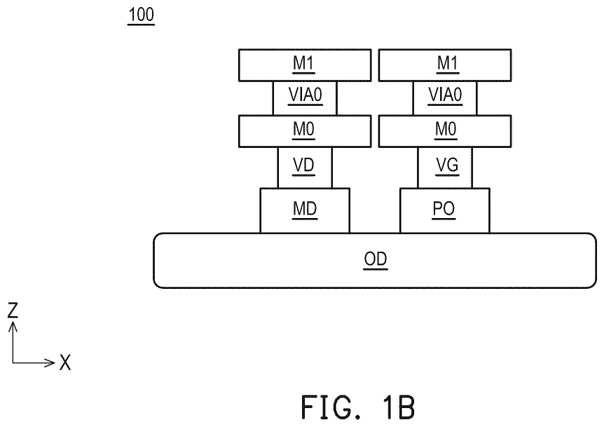

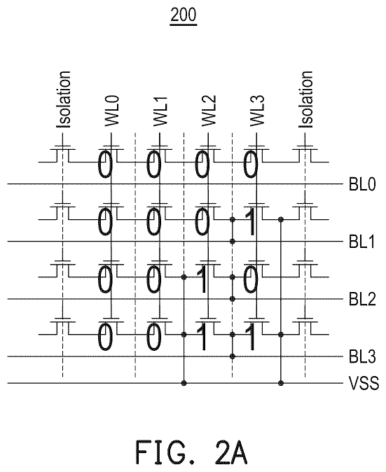

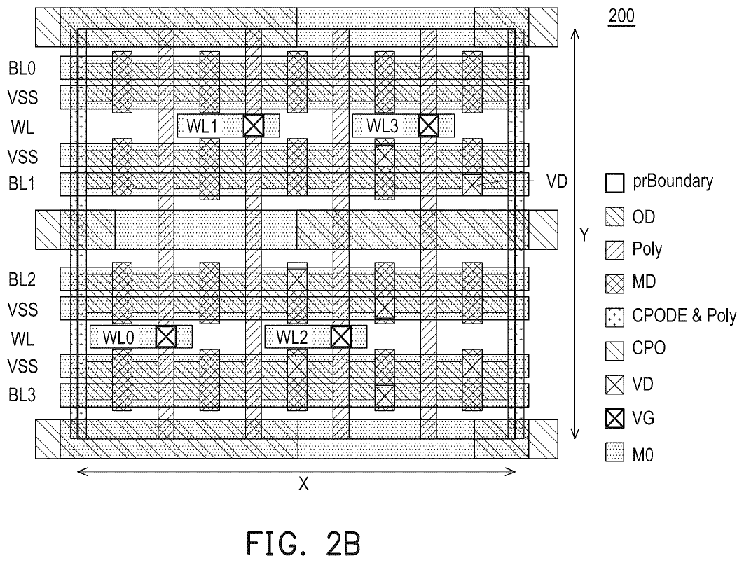

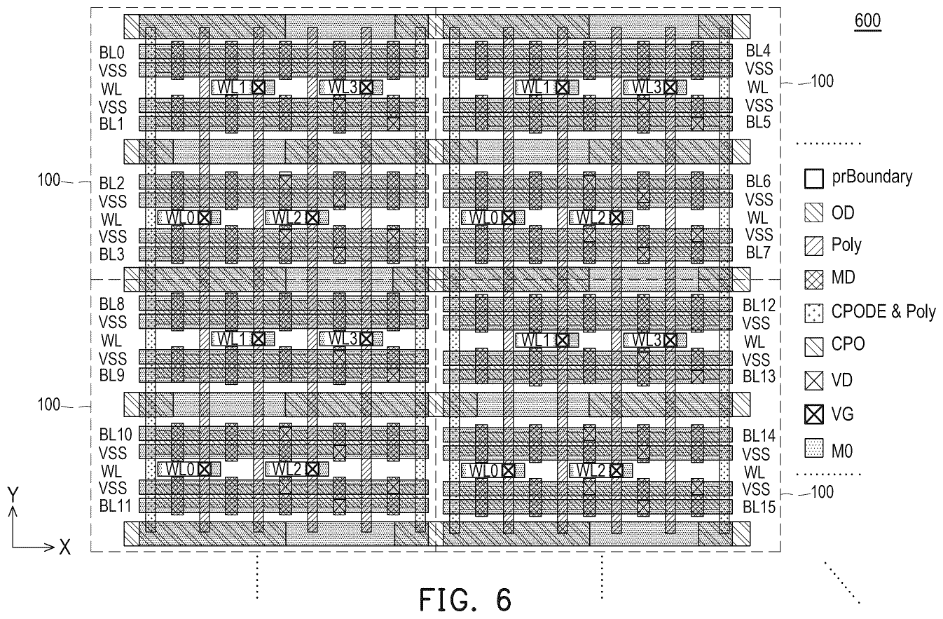

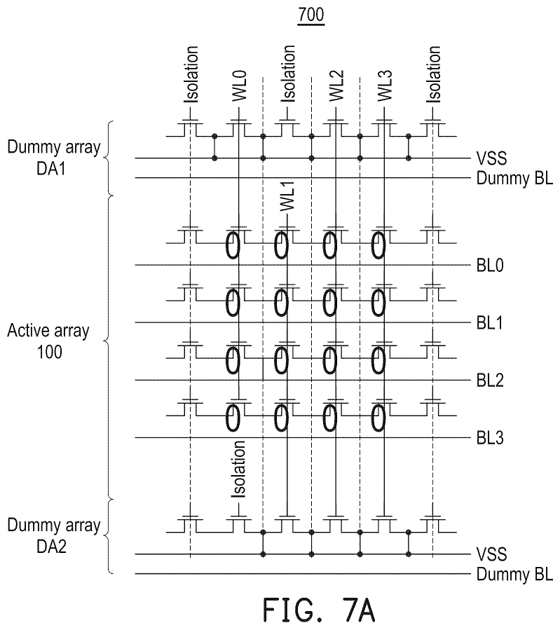

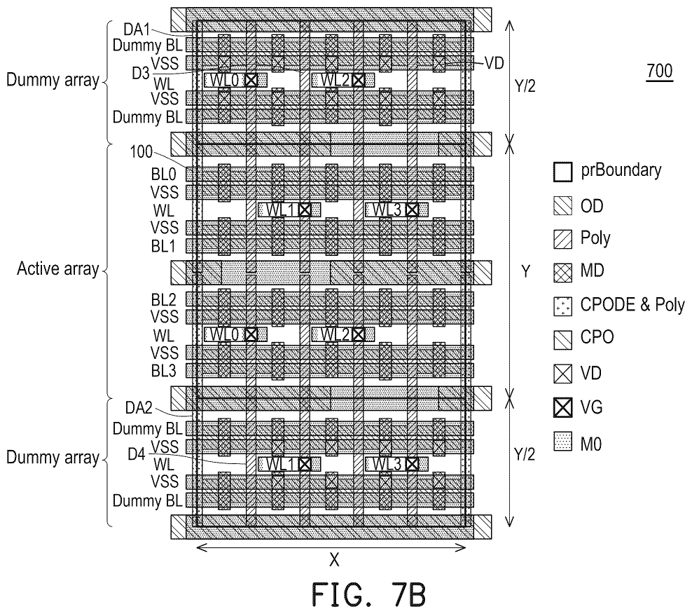

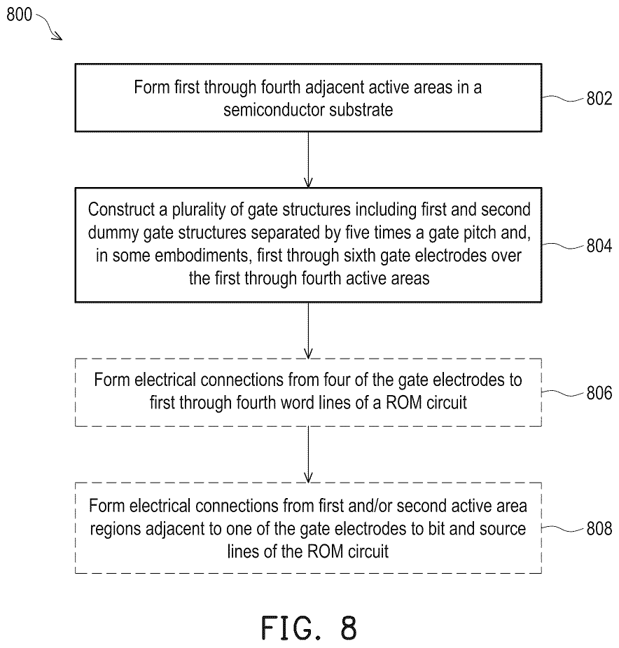

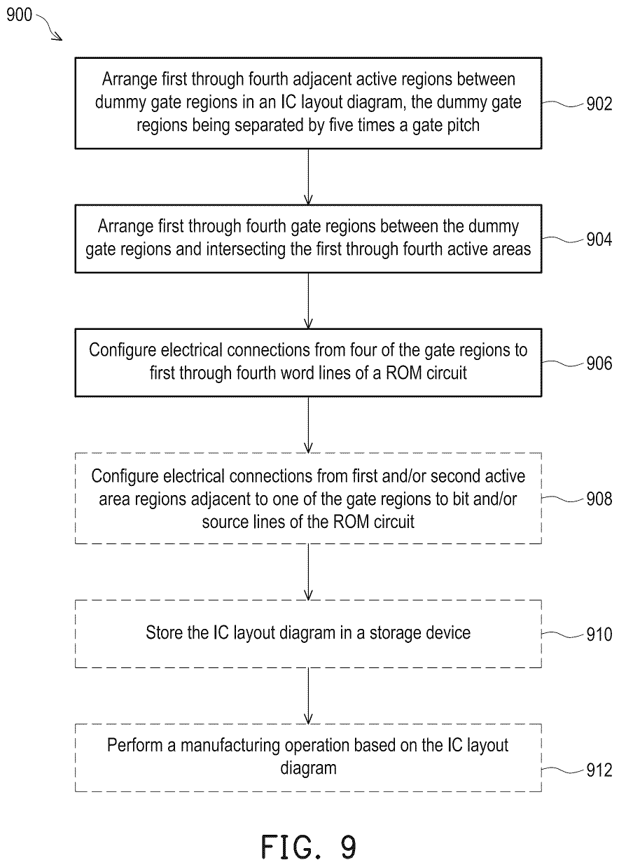

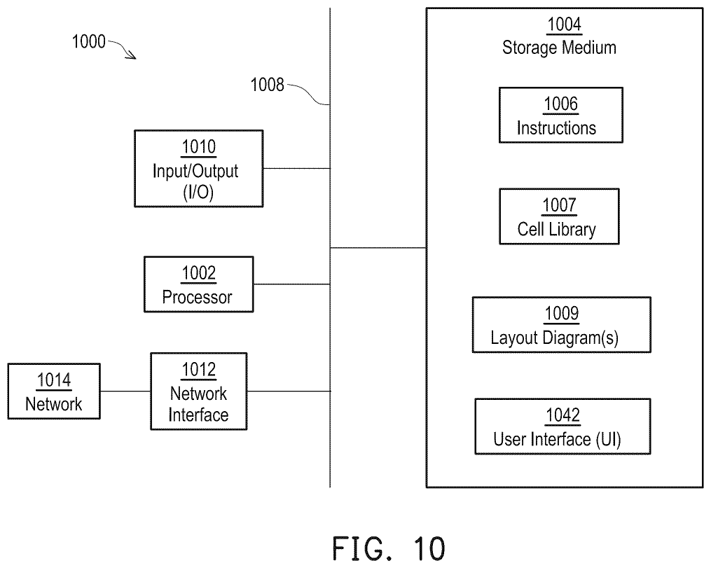

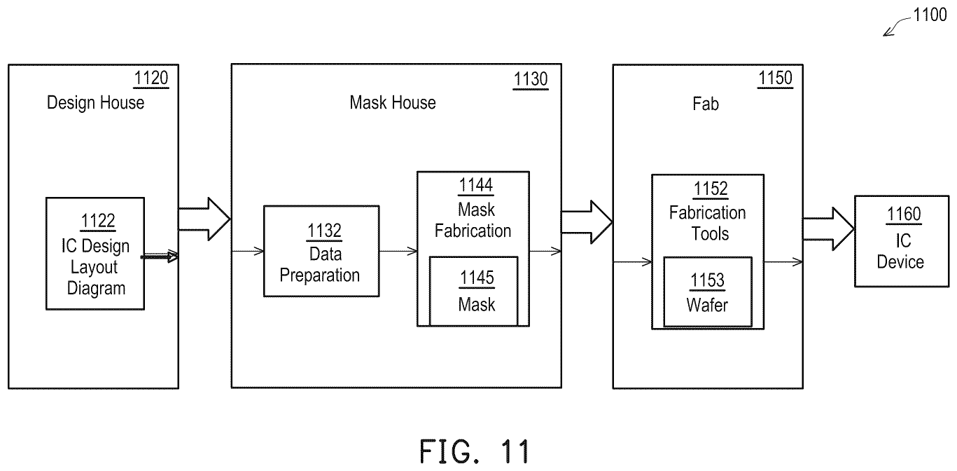

As discussed below, in accordance with various embodiments, FIGS. 1A and 1B are plan and side views of a NOR-type ROM IC device and layout diagram 100, FIGS. 2A-5B depict schematic diagrams and corresponding IC devices/layout diagrams 200-500 representing non-limiting examples of programmed states of IC device/layout diagram 100, FIG. 6 is a plan view of a NOR-type ROM IC device/layout diagram 600 including multiple instances of IC device/layout diagram 100, FIGS. 7A and 7B depict a schematic diagram and plan view of a NOR-type ROM IC device/layout diagram 700 including at least one instance of IC device/layout diagram 100, FIG. 8 is a flowchart of a method 800 of manufacturing a NOR-type ROM IC based on a corresponding one or more of IC layout diagrams 100-700, FIG. 9 is a flowchart of a method 900 of generating one or more of IC layout diagrams 100-700, e.g., using a system 1000 discussed below with respect to FIG. 10 and, e.g., in accordance with an IC manufacturing flow associated with an IC manufacturing system 1100 discussed below with respect to FIG. 11.

Each of the figures herein, e.g., FIGS. 1A-7B, is simplified for the purpose of illustration. The figures are views of IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, bulk connections, or other transistor elements, isolation structures, or the like, in addition to the features depicted in FIGS. 1A-7B.

In each of IC devices/layout diagrams 100-700, reference designators represent both IC device features and the IC layout features used to at least partially define the corresponding IC device features in a manufacturing process, e.g., method 800 discussed below with respect to FIG. 8 and/or the IC manufacturing flow associated with IC manufacturing system 1100 discussed below with respect to FIG. 11. Accordingly, each of IC devices/layout diagrams 100-700 represents a view of both an IC layout diagram 100-700 and a corresponding IC device 100-700.

FIG. 1A depicts IC device/layout diagram 100, X and Y directions, and a key corresponding to the features discussed below, in accordance with some embodiments.

IC device/layout diagram 100 includes active regions/areas A0-A3 extending in the X direction, referred to as adjacent active regions/areas based on IC device/layout diagram 100 being free from including additional active regions/areas between active regions/areas A0-A3.

Each active region/area A0-A3 extends from a dummy gate region/structure D1 to a dummy gate region/structure D2, each of which extends in the Y direction, and gate regions/structures G0-G5 extend in the Y direction between dummy gate regions/structures D1 and D2. Each of gate regions/structures G0 and G1 intersects/overlaps each of active regions/areas A0-A3, each of gate regions/structures G2 and G3 intersects/overlaps each of active regions/areas A0 and A1, and each of gate regions/structures G4 and G5 intersects/overlaps each of active regions/areas A2 and A3.

Gate region/structure G0 is offset from dummy gate region/structure D1 in the positive X direction by a pitch CPP, also referred to as a contact poly pitch CPP in some embodiments. Gate region/structure G1 is offset from gate region/structure G0 in the positive X direction by pitch CPP, each of gate regions/structures G2 and G4 is offset from gate region/structure G1 in the positive X direction by pitch CPP, gate region/structure G3 is offset from gate region/structure G2 in the positive X direction by pitch CPP, gate region/structure G5 is offset from gate region/structure G4 in the positive X direction by pitch CPP, and dummy gate region/structure D2 is offset from each of gate regions/structures G3 and G5 in the positive X direction by pitch CPP.

IC layout diagram 100 includes a boundary PR, also referred to as a place-and-route boundary PR or prBoundary PR in some embodiments, corresponding to an enclosed region in an IC layout diagram usable for routing signal and power connections, e.g., as part of an automated place-and-route (APR) algorithm. Dummy gate regions D1 and D2 extend along the vertical portions of boundary PR.

IC layout diagram 100 also includes cut gate regions CG (a single instance labeled for clarity) that extend in the X direction. The locations at which cut gate regions CG intersect gate regions in IC layout diagram 100 correspond to isolation structures ISO (a single instance labeled for clarity) in the corresponding IC device 100.

Each of gate regions G0 and G1 has two endpoints at instances of cut gate region CG that extend along the horizontal portions of boundary PR and correspond to two instances of isolation structure ISO. Gate regions G2 and G4 have single endpoints at a same instance of cut gate region CG corresponding to a single instance of isolation structure ISO, and gate regions G3 and G5 have single endpoints at a same instance of cut gate region CG corresponding to a single instance of isolation structure ISO.

Adjacent to each location at which a gate region/structure G0-G5 intersects/overlaps an active region/area A1-A4, the corresponding active region/area A0-A3 includes two instances of a source/drain (S/D) region/structure SD and an overlying MD region/segment MD (a single instance labeled collectively as SD/MD for clarity). As used herein, the terms S/D region(s)/structure(s) may refer to a source or a drain, individually or collectively dependent upon the context.

Bit lines BL0-BL3 and four instances of a source line VSS are metal regions/segments that extend in the X direction in a first metal layer and intersect/overlie respective active regions/areas A0-A3. In some embodiments, as depicted in FIG. 1A, additional metal regions/segments (not labeled for the purpose of clarity), e.g., signal or power lines, extend in the X direction in the first metal layer between corresponding pairs of bit lines BL0-BL3 and source lines VSS.

Via regions/structures VG (a single instance labeled for clarity) intersect/overlie each of gate regions/structures G0, G1, G3, and G4. A metal region/segment WL0 intersects/overlies gate region/structure G0 and the corresponding via region/structure VG, a metal region/segment WL1 intersects/overlies gate region/structure G1 and the corresponding via region/structure VG, a metal region/segment WL2 intersects/overlies gate region/structure G4 and the corresponding via region/structure VG, and a metal region/segment WL3 intersects/overlies gate region/structure G3 and the corresponding via region/structure VG.

Each of metal regions/segments WL0, WL1, WL2, and WL3 and the corresponding via region/structure VG is a portion of a corresponding word line (labeled generically as word line WL) electrically connected to the corresponding gate region/structure G0, G1, G3, or G4. In some embodiments, metal regions/segments WL0-WL3 are referred to as word lines WL0-WL3.

In some embodiments, e.g., IC device/layout diagram 600 or 700 discussed below with respect to FIGS. 6-7B, gate region/structure G2 extends beyond IC device/layout 100 in the positive Y direction (not shown in FIG. 1A) and an instance of metal region/segment WL2 intersects/overlies the extended portion of gate region/structure G2 and corresponding via region/structure VG, and/or gate region/structure G5 extends beyond IC device/layout 100 in the negative Y direction (not shown in FIG. 1A) and an instance of metal region/segment WL3 intersects/overlies the extended portion of gate region/structure G5 and corresponding via region/structure VG.

An active region/area, e.g., active region/area A0-A3, is a region in an IC layout diagram included in a manufacturing process as part of defining an active area, also referred to as an oxide diffusion or definition (OD), in a semiconductor substrate, either directly or in an n-well or p-well region/area (not shown for the purpose of clarity), in which one or more IC device features, e.g., a S/D structure, is formed. In some embodiments, an active area is an n-type or p-type active area of a planar transistor, a FinFET, or a GAA transistor. In various embodiments, an active area (structure) includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material.

In some embodiments, an active area is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

In the embodiments discussed herein, each instance of active region/area A0-A3 is a same one of an n-type or p-type active region/area, e.g., a p-type active region/area corresponding to n-type ROM bits as discussed below.

A S/D region/structure, e.g., S/D region/structure SD, is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a planar FET, a fin structure of a FinFET, or a gate structure of a GAA transistor. In some embodiments, a S/D region/structure includes one or more portions having doping concentrations greater than one or more doping concentrations present in the corresponding channel feature. In some embodiments, a S/D region/structure includes epitaxial regions of a semiconductor material, e.g., Si, SiGe, and/or silicon-carbide SiC.

An MD region/segment, e.g., MD region/segment MD, is a conductive region in the IC layout diagram included in the manufacturing process as part of defining an MD segment, also referred to as a conductive segment or MD conductive line or trace, in and/or on the semiconductor substrate. In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., the first metal layer. In various embodiments, an MD segment includes one or more of copper (Cu), silver (Ag), tungsten (W), titanium (Ti), nickel (Ni), tin (Sn), aluminum (A1) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of the semiconductor substrate and/or an epitaxial layer having a doping level, e.g., based on an implantation process, sufficient to cause the segment to have the low resistance level. In various embodiments, a doped MD segment includes one or more dopant materials having doping concentrations of about 1*10¹⁶ per cubic centimeter (cm⁻³) or greater.

In some embodiments, a manufacturing process includes two MD layers, and an MD region/segment, e.g., MD region/segment MD, refers to both of the two MD layers in the manufacturing process.

A gate region/structure, e.g., a gate region/structure G0-G5, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (A1), tungsten (W), cobalt (Co), ruthenium (Ru), or one or more other metals or other suitable materials, substantially surrounded by one or more insulating materials, the one or more conductive segments thereby being configured to control a voltage provided to an adjacent gate dielectric layer.

A gate dielectric layer, e.g., a gate dielectric layer of a gate structure G0-G5, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

A cut gate region, e.g., a cut gate region CG, also referred to as a cut poly (CPO) region CG in some embodiments, is a region in the IC layout diagram included in the manufacturing process as part of defining a portion of a gate electrode that is removed and replaced with one or more dielectric materials in operations performed subsequent to the gate electrode formation, thereby electrically isolating the adjacent portions of the gate electrode from each other.

An isolation feature/structure, e.g., isolation feature/structure ISO, is a feature including one or more regions in the IC layout diagram included in the manufacturing process as part of defining an isolation structure configured to electrically isolate adjacent features from each other, e.g., adjacent gate electrode portions based on a cut gate region of the IC layout diagram. In some embodiments, an isolation feature/structure, e.g., isolation feature/structure ISO, includes a dielectric region/volume positioned between the adjacent features, e.g., gate regions/structures G2 and G4 or G3 and G5. A dielectric region is a region in the IC layout diagram included in the manufacturing process as part of defining a volume including one or more insulating materials.

In some embodiments, an isolation feature/structure includes a dielectric region corresponding to a dummy, e.g., electrically isolated, gate region/structure, e.g., dummy gate region/structure D1 or D2. In some embodiments, a dummy gate region/structure includes a gate region/structure electrically connected, e.g., tied-off, to one or more features, e.g., an adjacent instance of S/D region/structure SD, whereby a corresponding transistor is switched off. In some embodiments, a dummy gate region/structure that overlaps/overlies an edge of an active region/area, e.g., dummy gate region/structure D1 or D2, is referred to as a continuous poly on oxide definition edge (CPODE) region/structure.

A metal line or region, e.g., power supply line VSS or bit line BL, is a region in the IC layout diagram included in the manufacturing process as part of defining a metal line structure including one or more conductive materials, e.g., polysilicon, copper (Cu), aluminum (Al), tungsten (W), cobalt (Co), ruthenium (Ru), or one or more other metals or other suitable materials, in a given metal layer of the manufacturing process. In various embodiments, a metal region/segment corresponds to a first metal layer (also referred to as a metal zero layer M0 in some embodiments), or a second or higher level metal layer, e.g., metal layer M1 discussed below, of the manufacturing process.

A via region/structure, e.g., a via region/structure VG, or VD discussed below, is a region in the IC layout diagram included in the manufacturing process as part of defining a via structure including one or more conductive materials configured to provide an electrical connection between an overlying conductive structure, e.g., a metal segment WL0-WL3 or a metal line VSS or BL, and an underlying conductive structure, e.g., a gate electrode of a gate structure G0-G5, or an MD segment such as an instance of MD segment MD, or an S/D structure such as an instance of S/D structure SD.

FIG. 1B depicts a portion of the elements of IC device/layout diagram 100, the X direction, and a Z direction, in accordance with some embodiments. The elements depicted in FIG. 1B are not necessarily included in a same X-Z plane or aligned along the X direction as depicted, and are arranged as depicted solely for the purpose of illustration of relative locations along the Z direction.

As depicted in FIG. 1B, active region/area OD represents one of active regions/areas A0-A3. An MD region/segment MD is positioned on active region/area OD, a via region/structure VD is positioned on the MD region/segment MD, and a first metal region/segment M0 positioned in the first metal layer and on the via region/structure VD represents one of bit lines BL0-BL3 or source lines VSS. A first via region/structure VIA0 positioned on the first metal region/segment M0 and a first metal region/segment M1 positioned in the second metal layer and on the first via region/structure VIA0 represent further electrical connections to the one of bit lines BL0-BL3 or source line VSS.

A gate region/structure PO positioned on active region/area OD represents one of gate region/structures G0-G5. A via region/structure VG is positioned on the gate electrode of gate region/structure PO, and a second metal region/segment M0 positioned in the first metal layer and on the via region/structure VG represents one of metal regions/segments WL0-WL3. A second via region/structure VIA0 positioned on the second metal region/segment M0 and a second metal region/segment M1 positioned in the second metal layer and on the second via region/structure VIA0 represent further electrical connections of the word line corresponding to the one of metal regions/segments WL0-WL3.

By the configuration discussed above, IC device/layout diagram 100, also referred to as ROM array 100 in some embodiments, includes an array of four rows R0-R3 of ROM bits B(0,0)-B(3,3), each row including a total of four ROM bits (a single row highlighted and labeled for clarity). Each ROM bit B(0,0)-B(3,3) (corresponding to B(word line number, row number)) includes an intersection/overlap of a gate region/structure G0-G5 (electrically connected to a corresponding word line WL, e.g., including metal region/segment WL0-WL3) and an active region/area A0-A3 along with the two adjacent S/D regions/structures SD and overlying MD regions/segments MD.

A given ROM bit is considered to have a first logical state, e.g., a logic one, corresponding to a functional transistor by further including electrical connections between the two adjacent S/D regions/structures and each of the corresponding overlying bit line BL0-BL3 and source line VSS, e.g., through the MD region/segment MD and a corresponding via region/structure VD, as discussed below with respect to FIGS. 2A-5B. A given ROM bit is considered to have a second logical state, e.g., a logic zero, corresponding to a non-functional transistor by further including a single or no electrical connection between the two adjacent S/D regions/structures and the corresponding overlying bit line BL0-BL3 or source line VSS, or electrical connections between each of the adjacent S/D regions/structures and a single one of the overlying bit line BL0-BL3 or source line VSS.

In the embodiment depicted in FIG. 1A, IC device/layout diagram 100 is free from including an instance of via region/structure VD, and each ROM bit B(0,0)-B(3,3) thereby has the second logical state corresponding to no electrical connection to the corresponding overlying bit line BL0-BL3 or source line VSS. In some embodiments, e.g., the non-limiting examples of IC devices/layout diagrams 200-500 discussed below with respect to FIGS. 2A-5B, IC device/layout diagram 100 includes one or more of ROM bits B(0,0)-B(3,3) having the first logical state corresponding to electrical connections, including via region/structure VD, to each of the corresponding overlying bit line BL0-BL3 and source line VSS.

As depicted in FIG. 1A, the four ROM bits B(0,0)-B(3,0) of row R0 include a total of five S/D regions/structures SD corresponding to three of the S/D regions/structures SD being shared between adjacent ROM bits of the four ROM bits B(0,0)-B(3,0). ROM bits B(0,1)-B(3,1) of row R1, B(0,2)-B(3,2) of row R2, and B(0,3)-B(3,3) of row R3 (not labeled) are similarly configured.

IC device/layout 100 is thereby configured to include an array of ROM bits B(0,0)-B(3,3) including each of rows R0-R3 including a total of four ROM bits extending between dummy gate regions/structures D1 and D2 over a distance corresponding to five times pitch CPP. Compared to other approaches, e.g., those in which a total of two S/D regions shared among four ROM cells correspond to a row length of six times a gate pitch, IC device/layout diagram 100 is thereby capable of having a smaller area, reduced bit line length, and less variable bit line leakage.

FIGS. 2A-5B are schematic diagrams and plan views of IC devices/layout diagrams 200-500, in accordance with some embodiments. Each of IC devices/layout diagrams 200-500 is a non-limiting example of IC device/layout diagram 100 including ROM bits having each of the first logical state corresponding to a logic one (logic one ROM bit) and the second logical state corresponding to a logic zero (logic zero ROM bit).

Each of FIGS. 2B, 3B, 4B, and 5B includes various features labeled in FIG. 1 that are not labeled for the purpose of clarity. Each of FIGS. 2B, 3B, 4B, and 5B also includes instances of via region/structure VD (a single one labeled for clarity) as discussed below.

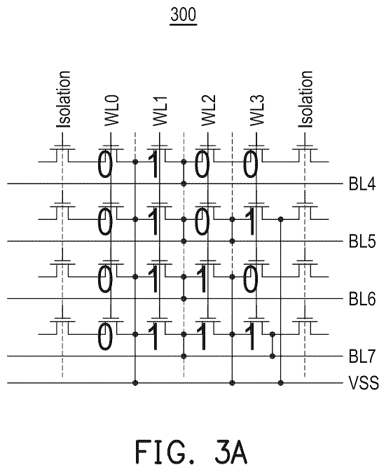

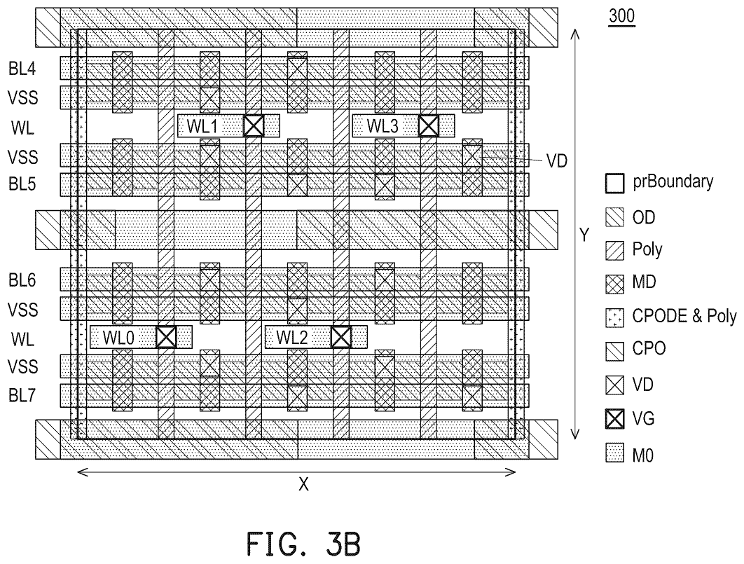

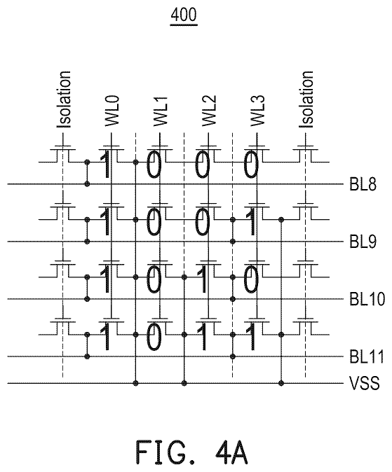

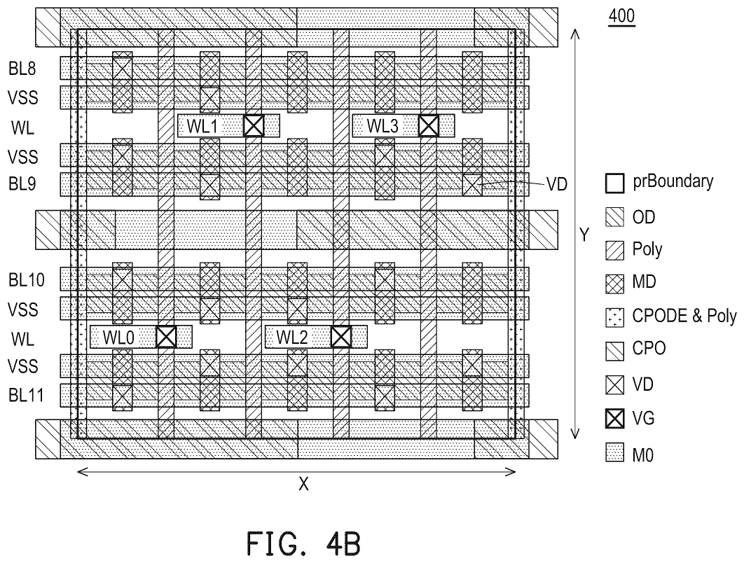

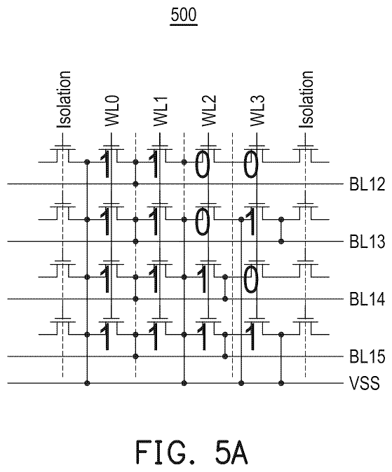

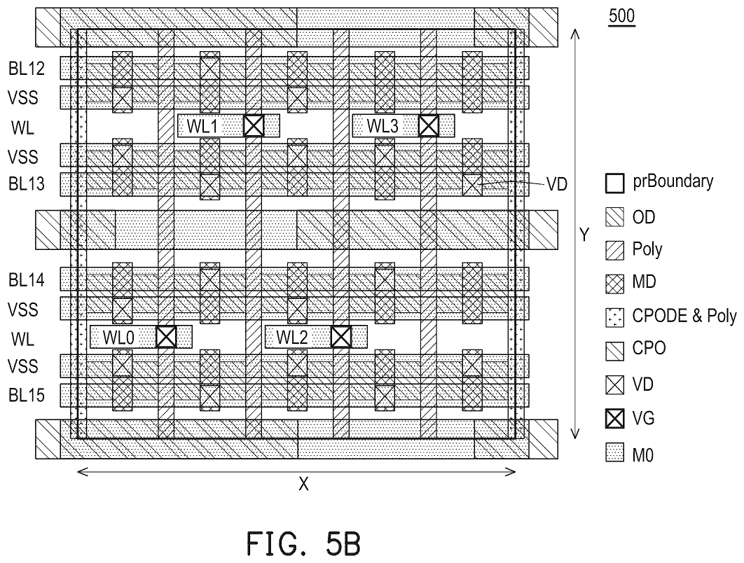

Instead of bit lines BL0-BL3, FIGS. 3A and 3B include bit lines BL4-BL7, FIGS. 4A and 4B include bit lines BL8-BL11, and FIGS. 5A and 5B include bit lines BL12-BL15. As discussed below, the four ROM bits corresponding to each of bit lines BL0-BL15 depicted in FIGS. 2A-5B represent non-limiting examples of bytes having values incrementing from 0000 to 1111.

As depicted in FIG. 2A, IC device/layout diagram 200 includes logic one ROM bits at locations corresponding to intersections of word line WL2 with each of bit lines BL2 and BL3 and intersections of word line WL3 with each of bit lines BL1 and BL3, and logic zero bits elsewhere. As depicted in FIG. 2B, each logic one ROM bit includes via regions/structures VD positioned between the adjacent MD regions/segments MD (and underlying S/D regions/structures SD) and corresponding overlying ones of bit lines BL1-BL3 and source lines VSS, and each logic zero ROM bit includes either zero via regions/structures VD or a single via region/structure VD corresponding to a S/D region/structure SD shared with an adjacent logic one ROM bit.

As depicted in FIG. 3A, IC device/layout diagram 300 includes logic one ROM bits at locations corresponding to intersections of word line WL1 with each of bit lines BL4-BL7, intersections of word line WL2 with each of bit lines BL6 and BL7, and intersections of word line WL3 with each of bit lines BL5 and BL7, and logic zero bits elsewhere. As depicted in FIG. 3B, each logic one ROM bit includes via regions/structures VD positioned between the adjacent MD regions/segments MD (and underlying S/D regions/structures SD) and corresponding overlying ones of bit lines BL4-BL7 and source lines VSS, and each logic zero ROM bit includes either zero via regions/structures VD, a single via region/structure VD corresponding to a S/D region/structure SD shared with an adjacent logic one ROM bit, or in the case of location B(WL2,BL5), via regions/structures VD positioned between each of the adjacent MD regions/segments MD and bit line BL5.

As depicted in FIG. 4A, IC device/layout diagram 400 includes logic one ROM bits at locations corresponding to intersections of word line WL0 with each of bit lines BL8-BL11, intersections of word line WL2 with each of bit lines BL10 and BL11, and intersections of word line WL3 with each of bit lines BL9 and BL11, and logic zero bits elsewhere. As depicted in FIG. 4B, each logic one ROM bit includes via regions/structures VD positioned between the adjacent MD regions/segments MD (and underlying S/D regions/structures SD) and corresponding overlying ones of bit lines BL8-BL11 and source lines VSS, and each logic zero ROM bit includes either zero via regions/structures VD, a single via region/structure VD corresponding to a S/D region/structure SD shared with an adjacent logic one ROM bit, or in the case of locations B(WL1,BL10) and B(WL1,BL11), via regions/structures VD positioned between each of the adjacent MD regions/segments MD and source line VSS.

As depicted in FIG. 5A, IC device/layout diagram 500 includes logic one ROM bits at locations corresponding to intersections of each of word lines WL0 and WL1 with each of bit lines BL12-BL15, intersections of word line WL2 with each of bit lines BL14 and BL15, and intersections of word line WL3 with each of bit lines BL13 and BL15, and logic zero bits elsewhere. As depicted in FIG. 5B, each logic one ROM bit includes via regions/structures VD positioned between the adjacent MD regions/segments MD (and underlying S/D regions/structures SD) and corresponding overlying ones of bit lines BL12-BL15 and source lines VSS, and each logic zero ROM bit includes either zero via regions/structures VD, a single via region/structure VD corresponding to a S/D region/structure SD shared with an adjacent logic one ROM bit, or in the case of location B(WL2,BL13), via regions/structures VD positioned between each of the adjacent MD regions/segments MD and source line VSS.

FIGS. 2A-5B thereby depict non-limiting examples of IC device/layout diagram 100 configured to include both logic one and logic zero ROM bits whereby byte values of 0000-1111 are programmed. Other configurations in which IC device/layout diagram 100 includes both logic one and logic zero ROM bits whereby byte values of 0000-1111 are programmed are within the scope of the present disclosure.

FIG. 6 depicts IC device/layout diagram 600, in accordance with some embodiments. IC device/layout diagram 600, also referred to as ROM array 600 in some embodiments, includes multiple instances of IC device/layout diagram 100 and the X and Y directions, discussed above with respect to FIGS. 1A-5B, in which various features labeled in FIG. 1 are not labeled for the purpose of clarity.

In the embodiment depicted in FIG. 6, IC device/layout diagram 600 includes a total of four instances (two columns and two rows) of IC device layout/diagram 100, each configured in accordance with the non-limiting example of IC device layout/diagram 200 discussed above with respect to FIGS. 2A and 2B, for the purpose of illustration. IC device/layout diagram 600 including other numbers of columns and rows, e.g., more than two columns and/or rows, and one or more configurations other than that of IC device layout/diagram 200 are within the scope of the present disclosure.

Each instance of IC device/layout diagram 100 includes electrical connections to each of word lines WL0-WL3. In some embodiments, IC device/layout diagram 600 includes electrical connections from each instance of a corresponding one of word lines WL0-WL3 to a common upper-level feature (not shown), e.g., an input/output (I/O) pad.

Instances of IC device/layout diagram 100 adjacent to each other along the Y direction including adjoining, thereby shared, gate regions/structures as discussed above with respect to FIGS. 1A and 1B, e.g., gate regions G2 and G4 included in an instance word line WL2 or gate regions G3 and G5 included in an instance of word line WL3. The corresponding instances of gate regions/structures G2/G4 and G3/G5 included in word lines WL2 and WL3 thereby have lengths in the Y direction equal to those of instances of gate regions/structures G0 and G1 included in word lines WL0 and WL1.

The instances of gate regions/structures G2/G4 and G3/G5 included in word lines WL2 and WL3 thereby also have staggered positions in the Y direction with respect to the instances of gate regions/structures G0 and G1 included in word lines WL0 and WL1, with the instances of metal regions/segments WL1 and WL3 aligned with each other in the X direction and the instances of metal regions/segments WL0 and WL2 aligned with each other in the X direction.

IC device/layout diagram 600 is thereby configured to include the multiple instances of IC device/layout diagram 100 including gate regions/structures corresponding to single word line electrical connections having equal lengths, thereby having more uniform parasitic capacitance, resistance, and leakage properties than other approaches, e.g., in which gate regions/segments corresponding to single word line electrical connections have lengths that vary significantly.

FIGS. 7A and 7B are a respective schematic diagram and plan view of IC device/layout diagram 700, in accordance with some embodiments. IC device/layout diagram 700, also referred to as ROM array 700 in some embodiments, includes IC device/layout diagram 100 and the X and Y directions, discussed above with respect to FIGS. 1A-6, in which various features labeled in FIG. 1 are not labeled for the purpose of clarity.

IC device/layout diagram 700 also includes a dummy array DA1 adjacent to IC device/layout diagram 100 in the positive Y direction and a dummy array DA2 adjacent to IC device/layout diagram 100 in the negative Y direction. Each of dummy arrays DA1 and DA2 includes two instances of active regions/areas corresponding to active regions/areas A0-A3 (not labeled for the purpose of clarity), two instances of overlapping/overlying metal regions/segments Dummy BL corresponding to bit lines BL0-BL3, and two instances of overlapping/overlying source lines VSS, each extending in the X direction between instances of dummy gate regions/structures D1 and D2 (not labeled for the purpose of clarity) as discussed above with respect to FIGS. 1A-6.

Dummy array DA1 further includes an instance of gate region/structure G0 (not labeled for the purpose of clarity) and corresponding metal region/segment WL0, a dummy gate region/structure D3, an extension of gate region/structure G2 and corresponding metal region/segment WL2, and an extension of gate region/structure G3. As depicted in FIGS. 7A and 7B, dummy array DA1 includes electrical connections (through instances of via regions/structures VD, a single one labeled for clarity) between each of the S/D regions/structures adjacent to each of gate regions/structures G0, G2, and G3 and the corresponding source line VSS.

Dummy array DA2 further includes a dummy gate region/structure D4, an instance of gate region/structure G1 (not labeled for the purpose of clarity) and corresponding metal region/segment WL1, an extension of gate region/structure G4, and an extension of gate region/structure G5 and corresponding metal region/segment WL3. As depicted in FIGS. 7A and 7B, dummy array DA2 includes electrical connections (through instances of via regions/structures VD, a single one labeled for clarity) between each of the S/D regions/structures adjacent to each of gate regions/structures G1, G4, and G5 and the corresponding source line VSS.

In the embodiment depicted in FIGS. 7A and 7B, IC device/layout diagram 700 includes single instances of each of IC device/layout diagram 100 (including all logic zero ROM bits) and dummy arrays DA1 and DA2 for the purpose of illustration. In some embodiments, IC device/layout diagram 700 includes more than one instance of one or more of IC device/layout diagram 100 and/or dummy arrays DA1 and/or DA2. In some embodiments, IC device/layout diagram 700 includes the one or more instances of IC device/layout diagram 100 including one or more logic one ROM bits in addition to or instead of the logic zero ROM bits, e.g., as discussed above with respect to FIGS. 2A-5B.

By including one or more instances of dummy arrays DA1 and/or DA2, IC device/layout diagram 700 includes gate regions/structures corresponding to single word line electrical connections having equal lengths and terminations based on source line connections, thereby enabling the uniform parasitic capacitance, resistance, and leakage properties discussed above with respect to IC device/layout diagram 600.

FIG. 8 is a flowchart of method 800 of manufacturing an IC device, in accordance with some embodiments. Method 800 is operable to form some or all of one or more of IC devices 100-700 discussed above with respect to FIGS. 1A-7B.

In some embodiments, performing some or all of the operations of method 800 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor wafer.

In some embodiments, the operations of method 800 are performed in the order depicted in FIG. 8. In some embodiments, the operations of method 800 are performed in an order other than the order depicted in FIG. 8. In some embodiments, one or more additional operations are performed before, during, and/or after the operations of method 800. In some embodiments, performing some or all of the operations of method 800 includes performing one or more operations as discussed below with respect to IC manufacturing system 1100 and FIG. 11.

At operation 802, first through fourth adjacent active areas are formed in a semiconductor substrate. In some embodiments, forming the first through fourth adjacent active areas includes forming active areas A0-A3 discussed above with respect to FIGS. 1A-7B.

Forming the first through fourth adjacent active areas includes forming the first through fourth adjacent active areas having a length in a first direction equal to five times a gate pitch, e.g., having the length in the X direction equal to five times gate pitch CPP discussed above with respect to FIGS. 1A-7B.

In some embodiments, forming the first through fourth adjacent active areas includes performing one or more deposition and/or implantation processes in areas of a semiconductor substrate corresponding to the one or more instances of IC 100-700. In some embodiments, forming the first through fourth adjacent active areas includes forming S/D structures and/or MD segments, e.g., S/D structures SD and/or MD segments MD discussed above with respect to FIGS. 1A-7B.

In some embodiments, forming the first through fourth adjacent active areas includes forming active areas in addition to the first through fourth active areas, e.g., fifth through eighth active areas aligned with the first through fourth active areas in the X or Y direction as discussed above with respect to FIG. 6, or configured in accordance with dummy array DA1 and/or DA2 as discussed above with respect to FIGS. 7A and 7B.

At operation 804, a plurality of gate structures is constructed on the first through fourth adjacent active areas. Constructing the plurality of gate structures includes constructing first and second dummy gate structures separated by five times a gate pitch and positioned over endpoints of the first through fourth adjacent active areas. In some embodiments, constructing the plurality of gate structures includes constructing dummy gate structures D1 and D2 discussed above with respect to FIGS. 1A-7B.

In some embodiments, constructing the first and second dummy gate structures includes constructing one or more dummy gate structures in addition to the first and second dummy gate structures, e.g., as discussed above with respect to FIGS. 6-7B.

In some embodiments, constructing the plurality of gate structures includes constructing first through sixth gate electrodes over the first through fourth active areas, e.g., gate structures G0-G5 including gate electrodes over active areas A0-A3 as discussed above with respect to FIGS. 1A-7B. In some embodiments, constructing the first through sixth gate electrodes includes forming isolation structures adjacent to each of the first through sixth gate electrodes, e.g., instances of isolation structure ISO discussed above with respect to FIGS. 1A-7B.

In some embodiments, constructing the plurality of gate structures includes constructing one or more gate structures in addition to those including the first through sixth gate electrodes, e.g., as discussed above with respect to FIGS. 6-7B.

In some embodiments, constructing the plurality of gate structures includes performing a plurality of manufacturing operations, e.g., one or more of a lithography, diffusion, deposition, etching, planarizing, or other operation suitable for constructing the plurality of gate structures as discussed above with respect to FIGS. 1A-7B.

At operation 806, in some embodiments, electrical connections from four of the gate electrodes to first through fourth word lines of a ROM circuit are formed. In some embodiments, forming the electrical connections includes forming metal segments WL0-WL3 of word lines WL0-WL3 discussed above with respect to FIGS. 1A-7B.

In some embodiments, forming electrical connections, e.g., by performing operations 806 and/or 808, includes forming one or more via structures and/or metal segments by performing a plurality of manufacturing operations including depositing and patterning one or more photoresist layers, performing one or more etching processes, and performing one or more deposition processes whereby one or more conductive materials are configured to form a continuous, low resistance structure.

At operation 808, in some embodiments, electrical connections are formed from first and/or second active area regions adjacent to one of the gate electrodes to bit and source lines of the ROM circuit. In some embodiments, forming the electrical connections from the first and/or second active area regions includes forming the electrical connections based on a ROM bit programming pattern.

In some embodiments, forming the electrical connections from the first and/or second active area regions adjacent to one of the gate electrodes to bit and source lines of the ROM circuit includes forming via structures VD over instances of S/D structures SD to one or more of bit lines BL0-BL15 and/or source lines VSS as discussed above with respect to FIGS. 1A-7B.

By performing some or all of the operations of method 800, an IC device is manufactured in which an array of ROM bits includes each of four rows including a total of four ROM bits extending between dummy gate structures over a distance corresponding to five times a gate pitch, thereby enabling the realization of the benefits discussed above with respect to IC devices 100-700.

FIG. 9 is a flowchart of method 900 of generating an IC layout diagram, e.g., one or more of IC layout diagrams 100-700 discussed above with respect to FIGS. 1A-7B, in accordance with some embodiments.

In some embodiments, generating the IC layout diagram includes generating the IC layout diagram corresponding to an IC device, e.g., IC device 100-700 discussed above with respect to FIGS. 1A-7B, manufactured based on the generated IC layout diagram.

In some embodiments, some or all of method 900 is executed by a processor of a computer, e.g., a processor 1002 of an IC layout diagram generation system 1000, discussed below with respect to FIG. 10.

Some or all of the operations of method 900 are capable of being performed as part of a design procedure performed in a design house, e.g., a design house 1120 discussed below with respect to FIG. 11.

In some embodiments, the operations of method 900 are performed in the order depicted in FIG. 9. In some embodiments, the operations of method 900 are performed simultaneously and/or in an order other than the order depicted in FIG. 9. In some embodiments, one or more operations are performed before, between, during, and/or after performing one or more operations of method 900.

At operation 902, first through fourth adjacent active regions are arranged between dummy gate regions in an IC layout diagram, the dummy gate regions being separated by five times a gate pitch. In some embodiments, arranging the first through fourth adjacent active regions between the dummy gate regions includes arranging active regions A0-A3 between dummy gate regions D1 and D2 separated by five times pitch CPP as discussed above with respect to FIGS. 1A-7B.

In some embodiments, arranging the first through fourth adjacent active regions includes arranging active regions in addition to the first through fourth adjacent active regions, e.g., as discussed above with respect to FIGS. 6-7B.

At operation 904, first through fourth gate regions are arranged between the dummy gate regions and intersecting the first through fourth active areas. In some embodiments, arranging the first through fourth gate regions includes arranging gate regions G0, G1, G2/G4, and G3/G5 between dummy gate regions D1 and D2 and intersecting active areas A0-A3 as discussed above with respect to FIGS. 1A-7B.

In some embodiments, arranging the first through fourth gate regions includes intersecting the first through fourth gate regions with cut gate regions, e.g., cut gate regions CG discussed above with respect to FIGS. 1A-7B.

In some embodiments, arranging the first through fourth gate regions includes arranging gate regions in addition to the first through fourth gate regions, e.g., as discussed above with respect to FIGS. 6-7B.

At operation 906, electrical connections from four of the gate regions to first through fourth word lines of a ROM circuit are configured in the IC layout diagram. In some embodiments, configuring the electrical connections from the four of the gate regions to the first through fourth word lines includes configuring metal regions WL0-WL4 and instances of via region VG as discussed above with respect to FIGS. 1A-7B.

In some embodiments, configuring the electrical connections from the four of the gate regions to the first through fourth word lines includes configuring electrical connections from one or more gate regions in addition to the four gate regions to the first through fourth word lines, e.g., as discussed above with respect to FIGS. 6-7B.

At operation 908, in some embodiments, electrical connections from first and/or second active area regions adjacent to one of the gate regions to bit and/or source lines of the ROM circuit are configured in the IC layout diagram. In some embodiments, configuring the electrical connections from the first and/or second active area regions adjacent to one of the gate regions to bit and/or source lines of the ROM circuit includes configuring instances of via region VD from one or more of S/D regions of active regions A0-A3 to one or more of bit lines BL0-BL15 and or source lines VSS as discussed above with respect to FIGS. 1A-7B.

In some embodiments, configuring the electrical connections from the first and/or second active area regions adjacent to one of the gate regions to bit and/or source lines of the ROM circuit includes configuring electrical connections from one or more active area regions in addition to the first and/or second active area regions to the bit and/or source lines of the ROM circuit, e.g., as discussed above with respect to FIGS. 2A-7B.

In some embodiments, configuring the electrical connections from the first and/or second active area regions adjacent to one of the gate regions to bit and/or source lines of the ROM circuit includes performing a ROM programming operation.

At operation 910, in some embodiments, the IC layout diagram including the first through fourth adjacent active regions and first through fourth gate regions is stored in a storage device. In some embodiments, storing the IC layout diagram in the storage device includes storing one or more of IC layout diagrams 100-700, discussed above with respect to FIGS. 1A-7B, in the storage device.

In various embodiments, storing the IC layout diagram in the storage device includes storing the IC layout diagram in a non-volatile, computer-readable memory or a cell library, e.g., a database, and/or includes storing the IC layout diagram over a network. In some embodiments, storing the IC layout diagram in the storage device includes storing the IC layout diagram in cell library 1007, in layout diagrams 1009, or over network 1014 of IC layout diagram generation system 1000, discussed below with respect to FIG. 10.

At operation 912, in some embodiments, one or more manufacturing operations are performed based on the IC layout diagram. In some embodiments, performing one or more manufacturing operations includes performing one or more lithographic exposures based on the IC layout diagram. Performing one or more manufacturing operations, e.g., one or more lithographic exposures, based on the IC layout diagram is discussed above with respect to FIG. 8 and below with respect to FIG. 11.

By executing some or all of the operations of method 900, an IC layout diagram is generated corresponding to an IC device in which an array of ROM bits includes each of four rows including a total of four ROM bits extending between dummy gate structures over a distance corresponding to five times a gate pitch, thereby enabling the realization of the benefits discussed above with respect to IC devices 100-700.

FIG. 10 is a block diagram of IC layout diagram generation system 1000, in accordance with some embodiments. Methods described herein of designing IC layout diagrams in accordance with one or more embodiments are implementable, for example, using IC layout diagram generation system 1000, in accordance with some embodiments.

In some embodiments, IC layout diagram generation system 1000 is a general purpose computing device including a hardware processor 1002 and a non-transitory, computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an electronic design automation (EDA) tool which implements a portion or all of a method, e.g., method 900 of generating an IC layout diagram described above with respect to FIG. 9 (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause IC layout diagram generation system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, computer-readable storage medium 1004 stores computer program code 1006 configured to cause IC layout diagram generation system 1000 (where such execution represents (at least in part) the EDA tool) to be usable for performing a portion or all of the noted processes and/or methods. In one or more embodiments, computer-readable storage medium 1004 also stores information which facilitates performing a portion or all of the noted processes and/or methods.

In one or more embodiments, computer-readable storage medium 1004 stores cell library 1007 of cells including such cells as disclosed herein, e.g., IC layout diagrams 100-500 discussed above with respect to FIGS. 1A-5B.

In one or more embodiments, computer-readable storage medium 1004 stores layout diagrams 1009 including such IC layout diagrams as disclosed herein, e.g., IC layout diagrams 600 and 700 discussed above with respect to FIGS. 6-7B.

IC layout diagram generation system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

IC layout diagram generation system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 1000.

IC layout diagram generation system 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. IC layout diagram generation system 1000 is configured to receive information related to a UI through I/O interface 1010. The information is stored in computer-readable medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of IC manufacturing system 1100, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns, e.g., one or more of IC layout diagrams 100-700 discussed above with respect to FIGS. 1A-7B. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (RDF). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes wafer fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some embodiments, a ROM array includes first through fourth rows of ROM bits including respective first through fourth adjacent active areas, wherein each of the first through fourth rows of ROM bits includes a total of four adjacent ROM bits positioned along the corresponding one of the first through fourth active areas, each ROM bit of the total of four ROM bits of each row of ROM bits includes two S/D regions in the corresponding active area, and three of the S/D regions of each row of ROM bits are shared by the four ROM bits. In some embodiments, the ROM array includes a first gate electrode shared by the first ROM bit of each of the first through fourth rows of ROM bits, a second gate electrode shared by the second ROM bit of each of the first through fourth rows of ROM bits, a third gate electrode shared by the third ROM bit of each of the first and second rows of ROM bits, a fourth gate electrode shared by the fourth ROM bit of each of the first and second rows of ROM bits, a fifth gate electrode shared by the third ROM bit of each of the third and fourth rows of ROM bits, and a sixth gate electrode shared by the fourth ROM bit of each of the third and fourth rows of ROM bits. In some embodiments, each of the first through fourth active areas extends between first and second dummy gate structures, the first and second dummy gate structures and first through sixth gate electrodes are spaced apart in accordance with a gate pitch, and the first and second dummy gate structures are separated by distance corresponding to five times the gate pitch. In some embodiments, the ROM array includes a first isolation structure positioned between the third and fifth gate electrodes and a second isolation structure positioned between the fourth and sixth gate electrodes. In some embodiments, the first gate electrode is electrically connected to a first word line exclusively through a first gate via positioned between the third and fourth active areas, the second gate electrode is electrically connected to a second word line exclusively through a second gate via positioned between the first and second active areas, the fifth gate electrode is electrically connected to a third word line exclusively through a third gate via positioned between the third and fourth active areas, and the sixth gate electrode is electrically connected to a fourth word line exclusively through a fourth gate via positioned between the first and second active areas. In some embodiments, the ROM array includes fifth through eighth rows of ROM bits including respective fifth through eighth adjacent active areas, wherein the fifth active area is adjacent to the fourth active area, each of the fifth through eighth rows of ROM bits includes a total of four adjacent ROM bits positioned along the corresponding one of the fifth through eighth active areas, the fifth gate electrode is further shared by the third ROM bit of each of the fifth and sixth rows of ROM bits, and the sixth gate electrode is further shared by the fourth ROM bit of each of the fifth and sixth rows of ROM bits, a seventh gate electrode shared by the first ROM bit of each of the fifth through eighth rows of ROM bits, an eighth gate electrode shared by the second ROM bit of each of the fifth through eighth rows of ROM bits, a ninth gate electrode shared by the third ROM bit of each of the seventh and eighth rows of ROM bits, and a tenth gate electrode shared by the fourth ROM bit of each of the seventh and eighth rows of ROM bits. In some embodiments, the ROM array includes first and second rows of dummy ROM bits including respective fifth and sixth adjacent active areas, wherein the fifth active area is adjacent to the fourth active area, each row of the first and second rows of dummy ROM bits includes a total of three dummy ROM bits positioned along the corresponding one of the fifth or sixth active areas, the fifth gate electrode is further shared by the second dummy ROM bit of each of the first and second rows of dummy ROM bits, and the sixth gate electrode is further shared by the third dummy ROM bit of each of the first and second rows of dummy ROM bits, and a seventh gate electrode shared by the first dummy ROM bit of each of the first and second rows of dummy ROM bits. In some embodiments, the ROM array includes fifth through eighth rows of ROM bits including respective fifth through eighth adjacent active areas aligned with the respective first through fourth active areas, wherein each of the fifth through eighth rows of ROM bits includes a total of four adjacent ROM bits positioned along the corresponding one of the fifth through eighth active areas, each ROM bit of the total of four ROM bits of each of the fifth through eighth rows of ROM bits includes two S/D regions in the corresponding active area, and three of the S/D regions of each of the fifth through eighth rows of ROM bits are shared by the four ROM bits. In some embodiments, the ROM array includes first through fourth bit lines and first through fourth source lines overlying the respective first through fourth rows of ROM bits, wherein at last one ROM bit of the four ROM bits of the first through fourth rows of ROM bits includes a first via extending from one of the two S/D regions to a corresponding one of the first through fourth bit lines and a second via extending from the other of the two S/D regions to a corresponding one of the first through fourth source lines.

In some embodiments, an IC device includes first through fourth adjacent active areas extending between first and second dummy gate structures, a first gate electrode extending across each of the first through fourth active areas and offset from the first dummy gate structure by a gate pitch, a second gate electrode extending across each of the first through fourth active areas and offset from the first gate electrode by the gate pitch, a third gate electrode extending across each of the first and second active areas and offset from the second gate electrode by the gate pitch, a fourth gate electrode extending across each of the first and second active areas and offset from each of the third gate electrode and the second dummy gate structure by the gate pitch, a fifth gate electrode extending across each of the third and fourth active areas, offset from the second gate electrode by the gate pitch, and separated from the third gate electrode by a first isolation structure, and a sixth gate electrode extending across each of the third and fourth active areas, offset from each of the fifth gate electrode and the second dummy gate structure by the gate pitch, and separated from the fourth gate electrode by a second isolation structure. In some embodiments, the IC device includes a first metal segment positioned between the third and fourth active areas in a first metal layer and electrically connected to the first gate electrode through a first gate via, a second metal segment positioned between the third and fourth active areas in the first metal layer and electrically connected to the fifth gate electrode through a second gate via, a third metal segment positioned between the first and second active areas in the first metal layer and electrically connected to the second gate electrode through a third gate via, and a fourth metal segment positioned between the first and second active areas in the first metal layer and electrically connected to the fourth gate electrode through a fourth gate via. In some embodiments, the IC device includes fifth through eighth adjacent active areas extending between the first and second dummy gate structures, wherein the fifth active area is adjacent to the fourth active area and each of the fifth and sixth gate electrodes extends across the fifth and sixth active areas, a seventh gate electrode extending across each of the fifth through eighth active areas, aligned with the first gate electrode, and separated from the first gate electrode by a third isolation structure, an eighth gate electrode extending across each of the fifth through eighth active areas, aligned with the second gate electrode, and separated from the second gate electrode by a fourth isolation structure, a ninth gate electrode extending across each of the seventh and eighth active areas, aligned with the fifth gate electrode, and separated from the fifth gate electrode by a fifth isolation structure, a tenth gate electrode extending across each of the seventh and eighth active areas, aligned with the sixth gate electrode, and separated from the sixth gate electrode by a sixth isolation structure, a fifth metal segment positioned between the seventh and eighth active areas in the first metal layer and electrically connected to the first metal segment and to the seventh gate electrode through a fifth gate via, a sixth metal segment positioned between the seventh and eighth active areas in the first metal layer and electrically connected to the second metal segment and to the ninth gate electrode through a sixth gate via, a seventh metal segment positioned between the fifth and sixth active areas in the first metal layer and electrically connected to the third metal segment and to the eighth gate electrode through a seventh gate via, and an eighth metal segment positioned between the fifth and sixth active areas in the first metal layer and electrically connected to the fourth metal segment and to the sixth gate electrode through an eighth gate via. In some embodiments, the IC device includes fifth and sixth adjacent active areas extending between the first and second dummy gate structures, wherein the fifth active area is adjacent to the fourth active area, and each of the fifth and sixth gate electrodes extends across the fifth and sixth active areas, a third dummy gate structure extending across each of the fifth and sixth active areas and aligned with the first gate electrode, a seventh gate electrode extending across each of the fifth and sixth active areas, aligned with the second gate electrode, and separated from the second gate electrode by a third isolation structure, a fifth metal segment positioned between the fifth and sixth active areas in the first metal layer and electrically connected to the third metal segment and to the seventh gate electrode through a fifth gate via, a sixth metal segment positioned between the fifth and sixth active areas in the first metal layer and electrically connected to the fourth metal segment and to the sixth gate electrode through a sixth gate via, first and second source lines positioned in the first metal layer overlying the respective fifth and sixth active areas, first through fourth vias extending from the first source line to the fifth active area adjacent to each of the second, fifth, and sixth gate electrodes, and fifth through eighth vias extending from the second source line to the sixth active area adjacent to each of the second, fifth, and sixth gate electrodes. In some embodiments, the IC device includes fifth through eighth adjacent active areas extending between third and fourth dummy gate structures and aligned with the respective first through fourth active areas, a seventh gate electrode extending across each of the fifth through eighth active areas and offset from the third dummy gate structure by the gate pitch, an eighth gate electrode extending across each of the fifth through eighth active areas and offset from the seventh gate electrode by the gate pitch, a ninth gate electrode extending across each of the fifth and sixth active areas and offset from the eighth gate electrode by the gate pitch, a tenth gate electrode extending across each of the fifth and sixth active areas and offset from each of the ninth gate electrode and the fourth dummy gate structure by the gate pitch, an eleventh gate electrode extending across each of the seventh and eighth active areas, offset from the eighth gate electrode by the gate pitch, and separated from the ninth gate electrode by a third isolation structure, and a twelfth gate electrode extending across each of the seventh and eighth active areas, offset from each of the eleventh gate electrode and the fourth dummy gate structure by the gate pitch, and separated from the tenth gate electrode by a fourth isolation structure. In some embodiments, the IC device includes first through fourth bit lines and first through fourth source lines positioned in the first metal layer overlying the respective first through fourth active areas, a first via extending from one of the first through fourth bit lines to the corresponding one of the first through fourth active areas adjacent to a first side of one of the first through sixth gate electrode, and a second via extending from the corresponding one of the first through fourth source lines to the corresponding one of the first through fourth active areas adjacent to a second side of the one of the first through sixth gate electrodes.

In some embodiments, a method of manufacturing an IC device includes forming first through fourth adjacent active areas in a semiconductor substrate, and constructing a plurality of gate structures, constructing the plurality of gate structures including constructing first and second dummy gate structures over endpoints of each of the first through fourth active areas, constructing a first gate structure offset from the first dummy gate structure by a gate pitch, constructing the first gate structure including forming a first gate electrode extending over the first through fourth active areas, constructing a second gate structure offset from the first gate structure by the gate pitch, constructing the second gate structure including forming a second gate electrode extending over the first through fourth active areas, constructing a third gate structure offset from the second gate electrode by the gate pitch, constructing the third gate structure including forming a third gate electrode extending over the first and second active areas, forming a fourth gate electrode extending over the third and fourth active areas, and forming a first isolation structure between the third and fourth gate electrodes, and constructing a fourth gate structure offset from each of the third gate structure and the second dummy gate structure by the gate pitch, constructing the fourth gate structure including forming a fifth gate electrode extending over the first and second active areas, forming a sixth gate electrode extending over the third and fourth active areas, and forming a second isolation structure between the fifth and sixth gate electrodes. In some embodiments, forming the first through fourth adjacent active areas includes forming fifth through eighth adjacent active areas in the semiconductor substrate adjacent to the fourth active area, constructing the first and second dummy gate structures includes constructing the first and second dummy gate structures over endpoints of each of the fifth through eighth active areas, constructing the first gate structure includes forming a seventh gate electrode extending over the fifth through eighth active areas and a third isolation structure between the first and seventh gate electrodes, constructing the second gate structure includes forming an eighth gate electrode extending over the fifth through eighth active areas and a fourth isolation structure between the second and eighth gate electrodes, constructing the third gate structure includes forming the fourth gate electrode further extending over the fifth and sixth active areas, forming a ninth gate electrode extending over the seventh and eighth active areas, and forming a fourth isolation structure between the fourth and ninth gate electrodes, and constructing the fourth gate structure includes forming the sixth gate electrode further extending over the fifth and sixth active areas, forming a tenth gate electrode extending over the seventh and eighth active areas, and forming a fifth isolation structure between the sixth and tenth gate electrodes. In some embodiments, forming the first through fourth adjacent active areas includes forming fifth and sixth adjacent active areas in the semiconductor substrate adjacent to the fourth active area, constructing the first and second dummy gate structures includes constructing the first and second dummy gate structures over endpoints of each of the fifth and sixth active areas, constructing the first gate structure includes forming a third dummy gate structure extending over the fifth and sixth active areas, constructing the second gate structure includes forming an seventh gate electrode extending over the fifth and sixth active areas and a third isolation structure between the second and seventh gate electrodes, constructing the third gate structure includes forming the fourth gate electrode further extending over the fifth and sixth active areas, and constructing the fourth gate structure includes forming the sixth gate electrode further extending over the fifth and sixth active areas. In some embodiments, the method includes forming electrical connections including a first exclusive electrical connection from the first gate electrode to a first word line of a ROM circuit, a second exclusive electrical connection from the second gate electrode to a second word line of the ROM circuit, a third exclusive electrical connection from the fourth gate electrode to a third word line of the ROM circuit, and a fourth exclusive electrical connection from the fifth gate electrode to a fourth word line of the ROM circuit. In some embodiments, the method includes forming electrical connections including a first via on a first region of one of the first through fourth active areas adjacent to a first side of one of the first through sixth gate electrodes, a second via on a second region of the one of the first through fourth active areas adjacent to a second side of the one of the first through sixth gate electrodes, a first electrical connection from the first via to a bit line of a ROM circuit, and a second electrical connection from the second via to a source line of the ROM circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A read-only memory (ROM) array comprising:
first through fourth rows of ROM bits comprising respective first through fourth adjacent active areas,
wherein
each of the first through fourth rows of ROM bits comprises a total of four adjacent ROM bits positioned along the corresponding one of the first through fourth active areas,
each ROM bit of the total of four ROM bits of each row of ROM bits comprises two source/drain (S/D) regions in the corresponding active area, and
three of the S/D regions of each row of ROM bits are shared by the four ROM bits.

2. The ROM array of claim 1, further comprising:
a first gate electrode shared by the first ROM bit of each of the first through fourth rows of ROM bits;
a second gate electrode shared by the second ROM bit of each of the first through fourth rows of ROM bits;
a third gate electrode shared by the third ROM bit of each of the first and second rows of ROM bits;
a fourth gate electrode shared by the fourth ROM bit of each of the first and second rows of ROM bits;
a fifth gate electrode shared by the third ROM bit of each of the third and fourth rows of ROM bits; and
a sixth gate electrode shared by the fourth ROM bit of each of the third and fourth rows of ROM bits.

3. The ROM array of claim 2, wherein
each of the first through fourth active areas extends between first and second dummy gate structures,
the first and second dummy gate structures and first through sixth gate electrodes are spaced apart in accordance with a gate pitch, and
the first and second dummy gate structures are separated by distance corresponding to five times the gate pitch.

4. The ROM array of claim 2, further comprising:
a first isolation structure positioned between the third and fifth gate electrodes; and
a second isolation structure positioned between the fourth and sixth gate electrodes.

5. The ROM array of claim 2, wherein
the first gate electrode is electrically connected to a first word line exclusively through a first gate via positioned between the third and fourth active areas,
the second gate electrode is electrically connected to a second word line exclusively through a second gate via positioned between the first and second active areas,
the fifth gate electrode is electrically connected to a third word line exclusively through a third gate via positioned between the third and fourth active areas, and
the sixth gate electrode is electrically connected to a fourth word line exclusively through a fourth gate via positioned between the first and second active areas.

6. The ROM array of claim 2, further comprising:
fifth through eighth rows of ROM bits comprising respective fifth through eighth adjacent active areas, wherein
the fifth active area is adjacent to the fourth active area,
each of the fifth through eighth rows of ROM bits comprises a total of four adjacent ROM bits positioned along the corresponding one of the fifth through eighth active areas,
the fifth gate electrode is further shared by the third ROM bit of each of the fifth and sixth rows of ROM bits, and
the sixth gate electrode is further shared by the fourth ROM bit of each of the fifth and sixth rows of ROM bits;
a seventh gate electrode shared by the first ROM bit of each of the fifth through eighth rows of ROM bits;
an eighth gate electrode shared by the second ROM bit of each of the fifth through eighth rows of ROM bits;
a ninth gate electrode shared by the third ROM bit of each of the seventh and eighth rows of ROM bits; and
a tenth gate electrode shared by the fourth ROM bit of each of the seventh and eighth rows of ROM bits.

7. The ROM array of claim 2, further comprising:
first and second rows of dummy ROM bits comprising respective fifth and sixth adjacent active areas, wherein
the fifth active area is adjacent to the fourth active area,
each row of the first and second rows of dummy ROM bits comprises a total of three dummy ROM bits positioned along the corresponding one of the fifth or sixth active areas,
the fifth gate electrode is further shared by the second dummy ROM bit of each of the first and second rows of dummy ROM bits, and
the sixth gate electrode is further shared by the third dummy ROM bit of each of the first and second rows of dummy ROM bits; and
a seventh gate electrode shared by the first dummy ROM bit of each of the first and second rows of dummy ROM bits.

8. The ROM array of claim 1, further comprising:
fifth through eighth rows of ROM bits comprising respective fifth through eighth adjacent active areas aligned with the respective first through fourth active areas,
wherein
each of the fifth through eighth rows of ROM bits comprises a total of four adjacent ROM bits positioned along the corresponding one of the fifth through eighth active areas,
each ROM bit of the total of four ROM bits of each of the fifth through eighth rows of ROM bits comprises two S/D regions in the corresponding active area, and
three of the S/D regions of each of the fifth through eighth rows of ROM bits are shared by the four ROM bits.

9. The ROM array of claim 1, further comprising:
first through fourth bit lines and first through fourth source lines overlying the respective first through fourth rows of ROM bits,
wherein at last one ROM bit of the four ROM bits of the first through fourth rows of ROM bits comprises:
a first via extending from one of the two S/D regions to a corresponding one of the first through fourth bit lines; and
a second via extending from the other of the two S/D regions to a corresponding one of the first through fourth source lines.

10. An integrated circuit (IC) device comprising:
first through fourth adjacent active areas extending between first and second dummy gate structures;
a first gate electrode extending across each of the first through fourth active areas and offset from the first dummy gate structure by a gate pitch;
a second gate electrode extending across each of the first through fourth active areas and offset from the first gate electrode by the gate pitch;
a third gate electrode extending across each of the first and second active areas and offset from the second gate electrode by the gate pitch;
a fourth gate electrode extending across each of the first and second active areas and offset from each of the third gate electrode and the second dummy gate structure by the gate pitch;
a fifth gate electrode extending across each of the third and fourth active areas, offset from the second gate electrode by the gate pitch, and separated from the third gate electrode by a first isolation structure; and
a sixth gate electrode extending across each of the third and fourth active areas, offset from each of the fifth gate electrode and the second dummy gate structure by the gate pitch, and separated from the fourth gate electrode by a second isolation structure.

11. The IC device of claim 10, further comprising:
a first metal segment positioned between the third and fourth active areas in a first metal layer and electrically connected to the first gate electrode through a first gate via;
a second metal segment positioned between the third and fourth active areas in the first metal layer and electrically connected to the fifth gate electrode through a second gate via;
a third metal segment positioned between the first and second active areas in the first metal layer and electrically connected to the second gate electrode through a third gate via; and
a fourth metal segment positioned between the first and second active areas in the first metal layer and electrically connected to the fourth gate electrode through a fourth gate via.

12. The IC device of claim 11, further comprising:
fifth through eighth adjacent active areas extending between the first and second dummy gate structures, wherein
the fifth active area is adjacent to the fourth active area, and
each of the fifth and sixth gate electrodes extends across the fifth and sixth active areas;
a seventh gate electrode extending across each of the fifth through eighth active areas, aligned with the first gate electrode, and separated from the first gate electrode by a third isolation structure;
an eighth gate electrode extending across each of the fifth through eighth active areas, aligned with the second gate electrode, and separated from the second gate electrode by a fourth isolation structure;
a ninth gate electrode extending across each of the seventh and eighth active areas, aligned with the fifth gate electrode, and separated from the fifth gate electrode by a fifth isolation structure;
a tenth gate electrode extending across each of the seventh and eighth active areas, aligned with the sixth gate electrode, and separated from the sixth gate electrode by a sixth isolation structure;
a fifth metal segment positioned between the seventh and eighth active areas in the first metal layer and electrically connected to the first metal segment and to the seventh gate electrode through a fifth gate via;
a sixth metal segment positioned between the seventh and eighth active areas in the first metal layer and electrically connected to the second metal segment and to the ninth gate electrode through a sixth gate via;
a seventh metal segment positioned between the fifth and sixth active areas in the first metal layer and electrically connected to the third metal segment and to the eighth gate electrode through a seventh gate via; and
an eighth metal segment positioned between the fifth and sixth active areas in the first metal layer and electrically connected to the fourth metal segment and to the sixth gate electrode through an eighth gate via.

13. The IC device of claim 11, further comprising:
fifth and sixth adjacent active areas extending between the first and second dummy gate structures, wherein
the fifth active area is adjacent to the fourth active area, and
each of the fifth and sixth gate electrodes extends across the fifth and sixth active areas;
a third dummy gate structure extending across each of the fifth and sixth active areas and aligned with the first gate electrode;
a seventh gate electrode extending across each of the fifth and sixth active areas, aligned with the second gate electrode, and separated from the second gate electrode by a third isolation structure;
a fifth metal segment positioned between the fifth and sixth active areas in the first metal layer and electrically connected to the third metal segment and to the seventh gate electrode through a fifth gate via;
a sixth metal segment positioned between the fifth and sixth active areas in the first metal layer and electrically connected to the fourth metal segment and to the sixth gate electrode through a sixth gate via;
first and second source lines positioned in the first metal layer overlying the respective fifth and sixth active areas;
first through fourth vias extending from the first source line to the fifth active area adjacent to each of the second, fifth, and sixth gate electrodes; and
fifth through eighth vias extending from the second source line to the sixth active area adjacent to each of the second, fifth, and sixth gate electrodes.

14. The IC device of claim 11, further comprising:
fifth through eighth adjacent active areas extending between third and fourth dummy gate structures and aligned with the respective first through fourth active areas;
a seventh gate electrode extending across each of the fifth through eighth active areas and offset from the third dummy gate structure by the gate pitch;
an eighth gate electrode extending across each of the fifth through eighth active areas and offset from the seventh gate electrode by the gate pitch;
a ninth gate electrode extending across each of the fifth and sixth active areas and offset from the eighth gate electrode by the gate pitch;
a tenth gate electrode extending across each of the fifth and sixth active areas and offset from each of the ninth gate electrode and the fourth dummy gate structure by the gate pitch;
an eleventh gate electrode extending across each of the seventh and eighth active areas, offset from the eighth gate electrode by the gate pitch, and separated from the ninth gate electrode by a third isolation structure; and
a twelfth gate electrode extending across each of the seventh and eighth active areas, offset from each of the eleventh gate electrode and the fourth dummy gate structure by the gate pitch, and separated from the tenth gate electrode by a fourth isolation structure.

15. The IC device of claim 11, further comprising:
first through fourth bit lines and first through fourth source lines positioned in the first metal layer overlying the respective first through fourth active areas;
a first via extending from one of the first through fourth bit lines to the corresponding one of the first through fourth active areas adjacent to a first side of one of the first through sixth gate electrodes; and
a second via extending from the corresponding one of the first through fourth source lines to the corresponding one of the first through fourth active areas adjacent to a second side of the one of the first through sixth gate electrodes.

16. A method of manufacturing an integrated circuit (IC) device, the method comprising:
forming first through fourth adjacent active areas in a semiconductor substrate; and
constructing a plurality of gate structures, the constructing the plurality of gate structures comprising:
constructing first and second dummy gate structures over endpoints of each of the first through fourth active areas;
constructing a first gate structure offset from the first dummy gate structure by a gate pitch, the constructing first gate structure comprising forming a first gate electrode extending over the first through fourth active areas;
constructing a second gate structure offset from the first gate structure by the gate pitch, the constructing the second gate structure comprising forming a second gate electrode extending over the first through fourth active areas;
constructing a third gate structure offset from the second gate electrode by the gate pitch, the constructing the third gate structure comprising:
forming a third gate electrode extending over the first and second active areas;
forming a fourth gate electrode extending over the third and fourth active areas; and
forming a first isolation structure between the third and fourth gate electrodes; and
constructing a fourth gate structure offset from each of the third gate structure and the second dummy gate structure by the gate pitch, the constructing the fourth gate structure comprising:
forming a fifth gate electrode extending over the first and second active areas;
forming a sixth gate electrode extending over the third and fourth active areas; and
forming a second isolation structure between the fifth and sixth gate electrodes.

17. The method of claim 16, wherein
the forming the first through fourth adjacent active areas comprises forming fifth through eighth adjacent active areas in the semiconductor substrate adjacent to the fourth active area,
the constructing the first and second dummy gate structures comprises constructing the first and second dummy gate structures over endpoints of each of the fifth through eighth active areas,
the constructing the first gate structure further comprises forming a seventh gate electrode extending over the fifth through eighth active areas and a third isolation structure between the first and seventh gate electrodes,
the constructing the second gate structure further comprises forming an eighth gate electrode extending over the fifth through eighth active areas and a fourth isolation structure between the second and eighth gate electrodes,
the constructing the third gate structure further comprises:
forming the fourth gate electrode further extending over the fifth and sixth active areas;
forming a ninth gate electrode extending over the seventh and eighth active areas; and
forming a fourth isolation structure between the fourth and ninth gate electrodes, and
the constructing the fourth gate structure further comprises:
forming the sixth gate electrode further extending over the fifth and sixth active areas;
forming a tenth gate electrode extending over the seventh and eighth active areas; and
forming a fifth isolation structure between the sixth and tenth gate electrodes.

18. The method of claim 16, wherein
the forming the first through fourth adjacent active areas comprises forming fifth and sixth adjacent active areas in the semiconductor substrate adjacent to the fourth active area,
the constructing the first and second dummy gate structures comprises constructing the first and second dummy gate structures over endpoints of each of the fifth and sixth active areas,
the constructing the first gate structure further comprises forming a third dummy gate structure extending over the fifth and sixth active areas,
the constructing the second gate structure further comprises forming an seventh gate electrode extending over the fifth and sixth active areas and a third isolation structure between the second and seventh gate electrodes,
the constructing the third gate structure further comprises forming the fourth gate electrode further extending over the fifth and sixth active areas, and the constructing the fourth gate structure further comprises forming the sixth gate electrode further extending over the fifth and sixth active areas.

19. The method of claim 16, further comprising:
forming electrical connections comprising:
a first exclusive electrical connection from the first gate electrode to a first word line of a read-only memory (ROM) circuit;
a second exclusive electrical connection from the second gate electrode to a second word line of the ROM circuit;
a third exclusive electrical connection from the fourth gate electrode to a third word line of the ROM circuit; and
a fourth exclusive electrical connection from the fifth gate electrode to a fourth word line of the ROM circuit.

20. The method of claim 16, further comprising:
forming electrical connections comprising:
a first via on a first region of one of the first through fourth active areas adjacent to a first side of one of the first through sixth gate electrodes;
a second via on a second region of the one of the first through fourth active areas adjacent to a second side of the one of the first through sixth gate electrodes;
a first electrical connection from the first via to a bit line of a read-only memory (ROM) circuit; and
a second electrical connection from the second via to a source line of the ROM circuit.
